(19) United States
(12) Patent Application Publication
(10) Pub. No.: US 2021/0398829 A1
(43) Pub. Date: Dec. 23, 2021

(54) CERAMIC PEDESTAL WITH MULTI-LAYER HEATER FOR ENHANCED THERMAL UNIFORMITY

(71) Applicant: LAM RESEARCH CORPORATION, Fremont, CA (US)

(72) Inventor: Christopher GAGE, Campbell, CA (US)

(21) Appl. No.: 17/297,666

(22) PCT Filed: Nov. 25, 2019
(86) PCT No.: PCT/US2019/062953

§ 371 Date: May 27, 2021

Related U.S. Application Data
(60) Provisional application No. 62/773,601, filed on Nov. 30, 2018.

(51) Int. Cl. H01L 21/67; H01L 21/687

(52) U.S. Cl. CPC H01L 21/67103; H01L 21/68714; H01L 21/67248

(57) ABSTRACT

A substrate support for a substrate processing system configured to perform a deposition process on a substrate includes a pedestal having an upper surface configured to support a substrate and N heating layers vertically-stacked within the pedestal below the upper surface. Each of the N heating layers includes a respective resistive heating element. A watt density of the resistive heating element in at least one of the N heating layers varies in at least one radial zone of the substrate support relative to other radial zones of the substrate support.

### CROSS-REFERENCE TO RELATED APPLICATIONS

This application claims the benefit of U.S. Provisional Application No. 62/773,601, filed on Nov. 30, 2018. The entire disclosure of the application referenced above is incorporated herein by reference.

### FIELD

The present disclosure relates to a temperature tunable pedestal for an ALD substrate processing chamber.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems may be used to treat substrates such as semiconductor wafers. Examples of substrate treatments include etching, deposition, photoresist removal, etc. During processing, the substrate is arranged on a substrate support such as an electrostatic chuck and one or more process gases may be introduced into the processing chamber.

The one or more processing gases may be delivered by a gas delivery system to the processing chamber. In some systems, the gas delivery system includes a manifold connected by one or more conduits to a showerhead that is located in the processing chamber. In some examples, processes use atomic layer deposition (ALD) to deposit a thin film on a substrate.

### SUMMARY

A substrate support for a substrate processing system configured to perform a deposition process on a substrate includes a pedestal having an upper surface configured to support a substrate and N heating layers vertically-stacked within the pedestal below the upper surface. Each of the N heating layers includes a respective resistive heating element. A watt density of the resistive heating element in at least one of the N heating layers varies in at least one radial zone of the substrate support relative to other radial zones of the substrate support.

In other features, each of the resistive heating elements includes a resistive coil. At least one of the resistive coils has a different pitch than others of the resistive coils. Each of the resistive coils has a same pitch. The resistive heating elements in at least two of the N heating layers are aligned in a vertical direction. The watt density varies in an outer zone of the substrate support. The watt density varies in an inner zone of the substrate support.

In other features, each of the resistive heating elements is configured to receive 1/N of an overall power provided to all of the N heating layers in total. A diameter of each of the respective resistive heating elements is 90-99% of a diameter of the upper surface of the substrate support. A system includes the substrate support and further includes a controller configured to control power provided to the N heating layers based on a desired power ratio between respective ones of the N heating layers.

A system includes a substrate support configured to support a substrate during a deposition process. The substrate support includes a pedestal having an upper surface configured to support a substrate and N heating layers vertically-stacked within the pedestal below the upper surface. Each of the N heating layers includes a respective resistive heating element. A controller is configured to control power provided to the N heating layers based on a desired power ratio between respective ones of the N heating layers.

In other features, each of the resistive heating elements includes a resistive coil. At least one of the resistive coils has a different pitch than others of the resistive coils. Each of the resistive coils has a same pitch. The resistive heating elements in at least two of the N heating layers are aligned in a vertical direction. A watt density of the resistive heating element in at least one of the N heating layers varies in at least one radial zone of the substrate support relative to other radial zones of the substrate support. The watt density varies in an outer zone of the substrate support. The watt density varies in an inner zone of the substrate support.

In other features, each of the resistive heating elements is configured to receive 1/N of an overall power provided to all of the N heating layers in total. A diameter of each of the respective resistive heating elements is 90-99% of a diameter of the upper surface of the substrate support.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1A is a functional block diagram of an example of a substrate processing system according to the present disclosure;

FIG. 1B is an example substrate support according to the present disclosure;

FIG. 1C is another example of the substrate support of FIG. 1B;

FIG. 1D is an example of a resistive heating element of the substrate support according to the present disclosure;

FIG. 2 is an example heat map of an upper surface of a substrate support;

FIG. 3 is an example temperature controller according to the principles of the present disclosure; and

FIG. 4 illustrates an example method for controlling the temperature of a substrate support according to the principles of the present disclosure.

In the drawings, reference numbers may be reused to identify similar and/or identical elements.

### DETAILED DESCRIPTION

In film deposition processes such as atomic layer deposition (ALD) (or, in some examples, chemical vapor deposition (CVD)), various properties of the deposited film vary across a spatial (i.e., x-y coordinates of a horizontal plane) distribution. For example, substrate processing tools may have respective specifications for film thickness non-uniformity (NU), which may be measured as a full-range, a half-range, and/or a standard deviation of a measurement set taken at predetermined locations on a surface of a semiconductor substrate. In some examples, the NU may be reduced either by, for example, addressing a direct cause of the NU and/or introducing a counteracting NU to compensate and cancel the existing NU. In other examples, material may be intentionally deposited and/or removed non-uniformly to compensate for known non-uniformities at other (e.g. previous or subsequent) steps in a process. In these examples, a predetermined non-uniform deposition/removal profile may be calculated and used.

Various properties of deposited films may be influenced by a temperature of the substrate during deposition. For example, during a deposition process (e.g., deposition of an oxide film), a substrate is arranged on a substrate support such as an ALD pedestal. A temperature of the pedestal may be adjusted during the deposition process to control the temperature of the substrate to attempt to compensate for NUs. For example, the pedestal may include resistive heating elements that are controlled to control the temperature of the substrate.

Structural and control constraints of the pedestal limit the ability to compensate for all thermal NUs (e.g., thermal NUs resulting from various non-repeatable effects of fabrication) during processing. For example, an ALD pedestal may include only a single zone (i.e., a single adjustable temperature region). In other examples, the ALD pedestal may include two zones (e.g., a central zone and an annular outer zone surrounding the central zone). However, adjusting the temperature of the entire pedestal and/or substrate may not compensate for temperature NUs across a surface of the substrate.

In other examples, manufacturing and/or design limitations may cause NUs in the structure of the pedestal. For example, in pedestals configured for deposition processes performed at very high temperatures (e.g., aluminum nitride (AlN) ceramic pedestals), resistive heating elements are configured to operate at 400-800° C. or higher. Greater precision in operating characteristics of the resistive heating elements (e.g., watt density, heat generation uniformity, etc.) is required due to constraints associated with operation at these high temperatures, such as heat flux caused by radiation losses, a thermal conductivity of AlN (e.g., 50-60 Watts/m-K), etc. Physical characteristics of the heating elements and various types of defects may affect heat generation uniformity.

Typically, heating elements are provided in a single layer within a single zone or multi-zone pedestal. In a pedestal (e.g., an AlN pedestal) according to the principles of the present disclosure, heating elements are vertically-stacked to form a plurality of zones in respective heating layers (e.g., N heating layers). Accordingly, heat generation for a given area of the pedestal is distributed across multiple heating elements. In this manner, non-uniformities associated with any one of the heating elements in a given area are reduced.

For example, by vertically stacking multiple heating elements on top of each other, heat flux to discrete areas of the substrate is provided by multiple heating elements. With N (e.g., three) heating elements, power provided to each of the heating elements is reduced to 1/N of the power provided to the heating element of a pedestal with only a single layer of heating elements. If the heating element in each of the respective layers has a same thermal NU as the heating element in a conventional single-layer pedestal and the thermal NUs in the individual heating elements are not aligned in a vertical direction (i.e., the thermal NUs are not stacked directly on top of each other), a net thermal NU at the substrate would be reduced to 1/N. For example, with three heating elements in a vertically-stacked configuration, a thermal NU of 6° C. would be reduced to 2° C.

In some examples, the N layers may be configured to have a watt density bias in different radial regions to facilitate control of a power ratio between inner and outer regions of the pedestal. For example, with three layers, a top layer may be biased to have a greater watt density (e.g., 30% greater) in the outer region, a middle layer may have a watt density corresponding to predicted thermal boundary conditions, and a bottom layer may have a greater watt density (e.g., 30% greater) in an inner region. Because each zone (i.e., layer) is essentially the full size (e.g., 90-99% of the diameter) of the pedestal, required resistance ranges are more easily achieved. Further, a 1:1:1 power ratio between the zones may be achieved at nominal operating conditions. Accordingly, thermal uniformity is increased and precise and efficient zone ratio control is facilitated.

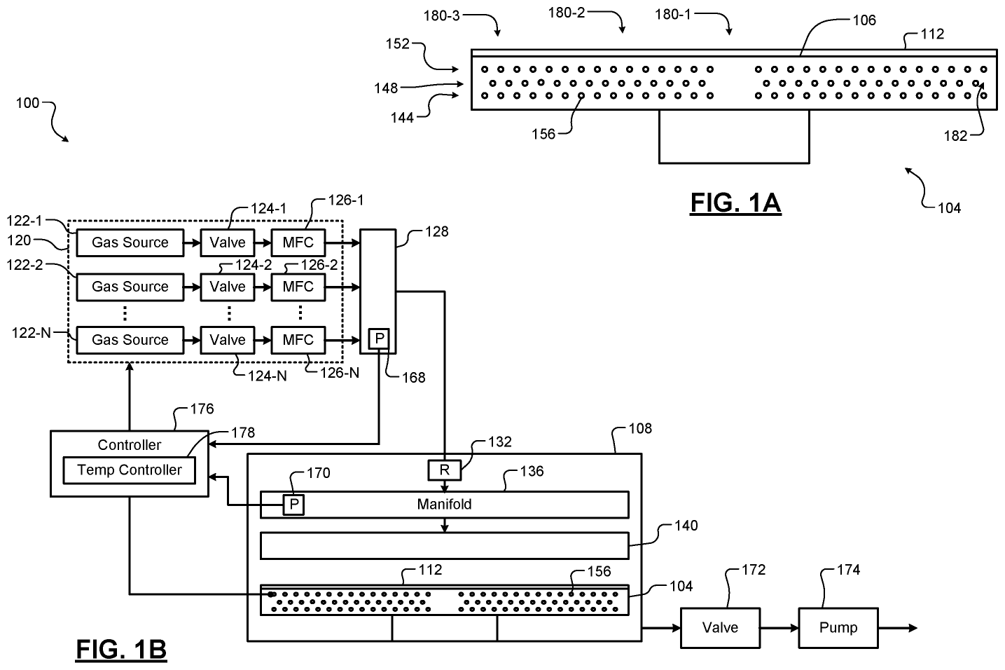

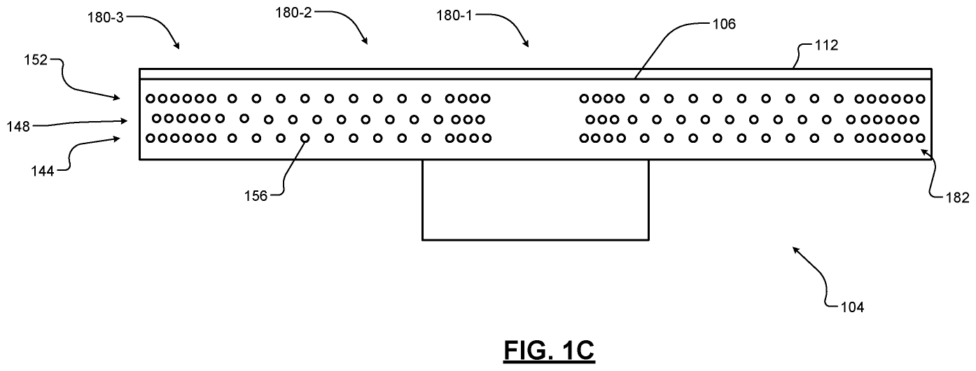

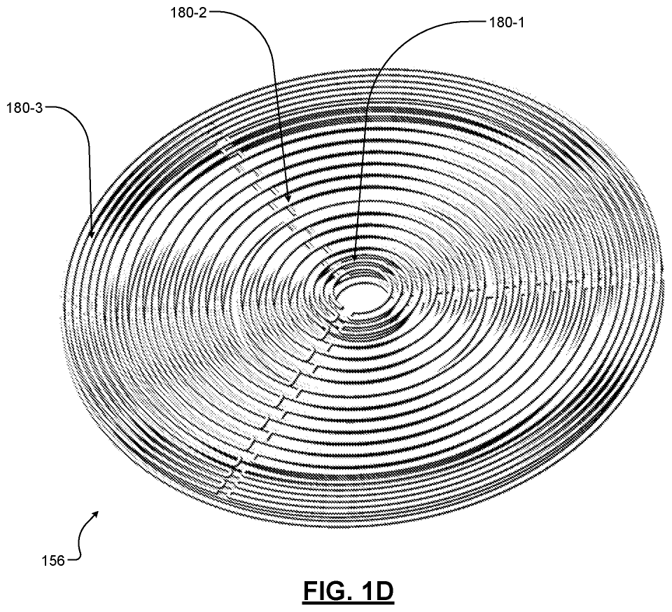

Referring now to FIGS. 1A, 1B, 1C, and 1D, an example of a substrate processing system 100 including a substrate support (e.g., an AlN ALD pedestal) 104 according to the present disclosure is shown. The substrate support 104 is arranged within a processing chamber 108. A substrate 112 is arranged on the substrate support 104 during processing. The substrate processing system 100 of FIG. 1B is shown for example purposes only and the substrate support 04 may be implemented within other substrate processing system configurations.

A gas delivery system 120 includes gas sources 122-1, 122-2, . . . , and 122-N (collectively gas sources 122) that are connected to valves 124-1, 124-2, . . . , and 124-N (collectively valves 124) and mass flow controllers 126-1, 126-2, . . . , and 126-N (collectively MFCs 126). The MFCs 126 control flow of gases from the gas sources 122 to a manifold 128 where the gases mix. An output of the manifold 128 is supplied via an optional pressure regulator 132 to a manifold 136. An output of the manifold 136 is input to a multi-injector showerhead 140. While the manifold 128 and 136 are shown, a single manifold can be used.

The substrate support 104 includes a plurality of vertically-stacked zones (i.e., N zones in a multi-layer arrangement). As shown, the substrate support 104 includes a lower zone 144, a middle zone 148, and an upper zone 152 in respective vertical layers of the substrate support 104 (e.g., N=3). For example, each zone may include a separately-controllable resistive heating element 156. For example, each of the resistive heating elements 156 may correspond to a resistive heating coil as shown in more detail in FIG. 1D. Each of the heating elements 156 has a diameter that is only slightly less than a diameter of an upper surface 106 the substrate support 104. For example, diameters of the heating elements 156 may be 90-99% of the diameter of the upper surface 106.

In some examples, pressure sensors 168, 170 may be arranged in the manifold 128 or the manifold 136, respectively, to measure pressure. A valve 172 and a pump 174 may be used to evacuate reactants from the processing chamber 108 and/or to control pressure within the processing chamber 108.

A controller 176 may control dosing provided by the multi-injector showerhead 140. The controller 176 also controls gas delivery from the gas delivery system 120. The controller 176 controls pressure in the processing chamber and/or evacuation of reactants using the valve 172 and the pump 174. The controller 176 is further configured to control the temperature of the substrate support 104 and the substrate 112 based upon temperature feedback (e.g., from one or more sensors (not shown) in the substrate support, temperature calculation models, etc.). For example, the controller 176 may include a temperature controller 178 configured to control the temperature of the substrate support 104 by separately providing power to the resistive heating elements 156 arranged in the respective zones 144, 148, and 152 as described below in more detail. Although shown integrated with the controller 176, in other examples the temperature controller 178 may be separate from the controller 176.

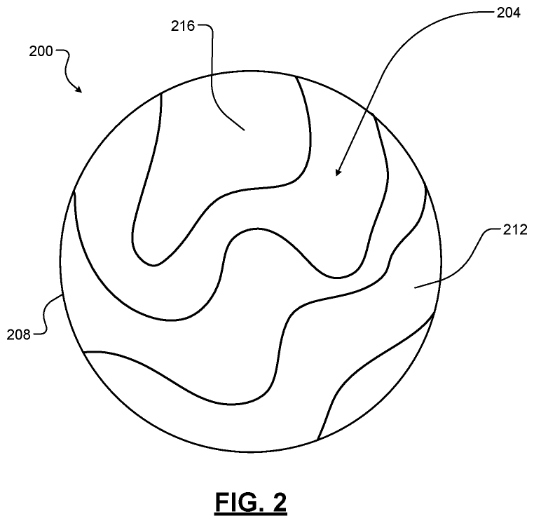

Referring now to FIG. 2, an example heat map 200 of an upper surface 204 of a substrate support 208 is shown. As shown, heat generation on the upper surface 204 is non-uniform, resulting in thermal NUs. Uniformity of heat generation (i.e., power output or generation) of a heating element is a function of resistance uniformity of the heating element. As resistance of the heating element varies throughout the coil, power output (and, therefore, heat output) varies. In one example, temperatures across the upper surface 204 may vary from an average of 509° C. in a first region 212 to an average of 515° C. in a second region 216 (i.e., a difference of 6° C.). An average temperature across the upper surface 204 may be 512° C. In other examples, the temperature difference may be greater than or less than 6° C.

A majority of power loss from the upper surface 204 may be attributed to radiation loss, a percentage difference in power flux from the second region 216 to the first region 212, etc. A relatively low power output difference (e.g., less than 5%) may correspond to a relatively significant difference in temperature (e.g., 5-15° C.) of the upper surface 204 in the respective regions 212 and 216.

The power generation (P) of a heating element is directly and linearly related to a resistance R of the heating element in accordance with (P=R×I²), where I is a current through the heating element. Accordingly, as resistances in different regions of the heating element vary, current, and therefore power output, also varies in the different regions, causing heat generation to vary. Causes of variation in resistance of the heating element include, but are not limited to, contamination or other defects in the material, variations in wire diameter, changes in resistivity (e.g., caused by oxidation, chemistry variation, variation in wire density, etc.), variations in geometry (e.g., positioning of the heater coil, a shape or position of the heating element pattern, etc.), and/or variations in the material of the pedestal (e.g., variations in a thickness of the AlN ceramic plate, variations in a thermal conductivity of the AlN, etc.). These and other variations can cause a variation in resistance between different regions of the heating element. Further, there may be additional variations in resistance between different pedestals

Referring again to FIGS. 1A-1D, heat generation for a given area of the substrate support 104 is distributed across the plurality of resistive heating elements 156 arranged in the respective zones 144, 148, and 152. For example, if the substrate support 104 includes N of the vertically-stacked heating elements 156 and a total power P is provided to the heating elements 156, the power provided to each of the heating elements (e.g., in response to commands from the controller 176) is 1/N*P. Further, if a thermal NU in a given area of one of the heating elements 156 is 10%, the corresponding heat generation NU attributed to that heating element 156 is 10% of (1/N)*P. In contrast, if the substrate support 104 included only one of the heating elements 156, the heating element 156 would receive the total power P and the corresponding heat generation NU attributed to that heating element would be 10% of P. Accordingly, by providing N of the heating elements 156, the heat generation NU is significantly reduced (e.g., by 2/N).

The above-described reduction in heat generation NU may assume a best case scenario where only one of the heating elements 156 in the given area has a thermal NU. In other words, an ideal reduction of 2/N may correspond to an arrangement where only one of the heating elements 156 has the thermal NU of 10% and the remaining heating elements 156 each have a thermal NU of 0%. In other examples, the remaining heating elements 156 may have thermal NUs of greater than 0% but less than 10%. In a worst case scenario, each of the N heating elements may have the thermal NU of 10%. However, even in the worst case scenario, the overall thermal NU would be 10% of P, or the same NU of an arrangement with only one of the heating elements 156 having a thermal NU of 10%.

In this manner, the magnitude of heat generation NUs across the substrate support 104 are significantly reduced because an arrangement where each of the N heating elements 156 has the same thermal NU in a given area is statistically improbable.

In some examples, the N layers may be configured to have a watt density bias in different radial regions (e.g., “radial zones”) of the substrate support 104 to facilitate control of a power ratio between inner and outer radial zones of the substrate support 104. Watt density corresponds to heating element power divided by an actively heated surface area. For example, as shown in FIGS. 1A, 1C, and 1D, the substrate support 104 may have a plurality (e.g., two or three) of radial zones such as an inner zone 180-1, a middle zone 180-2, and an outer zone 180-3, referred to collectively as radial zones 180. Parameters (e.g., a pitch) of the respective coils of the heating elements 156 may be varied across the radial zones 180 to provide different heat generation in the different radial zones 180.

In one example, the heating element 156 in a first one of the zones 144, 148, and 152 (e.g., the upper zone 152) may have a greater watt density (e.g., 20-40% greater) in the outer zone 180-3. For example, a pitch of the coil of the heating element 156 in the outer zone 180-3 may be greater than a pitch in remaining regions of the heating element 156 to increase the watt density bias in the outer zone 180-3. A relatively narrow width of the outer zone 180-3 (e.g., relative to the overall diameter of the substrate support 104) facilitates fine tuning of temperatures at an outer edge of the substrate 112 (e.g., at a diameter greater than 9.0″ (228.6 mm), 9.5″ (241.3 mm), 10.0″ (254 mm), 10.5″266.7 mm), etc.), of the substrate support 104).

The heating element 156 in a second one of the zones 180 (e.g., the middle zone 180-2) may have a watt density corresponding to predicted thermal boundary conditions of the substrate support 104. For example, a pitch of the coil of the heating element 156 in the middle zone 180-2 may vary in accordance with predicted thermal variations in a surface of the substrate support 104.

The heating element in a third (e.g., the lower zone 144) layer may have a greater watt density (e.g., 20-40% greater) in the inner zone 180-1. For example, a pitch of the coil of the heating element 156 in the inner zone 180-1 (e.g., at a diameter less than 3″, or 76.2 mm) may be greater than a pitch in remaining regions of the heating element 156 to increase the watt density bias in the inner zone 180-1.

In some examples, one or more of the heating elements 156 of the zones 144, 148, and 156 may include two or more separately controllable radial zones.

In some examples, power provided to each of the zones 144, 148, 152 is (1/N)*P (i.e., a power ratio of 1:1:1). In other words, power provided to each of the zones is equal. In other examples, a different power may be provided to each of the zones 144, 148, and 152. For example, the power ratio may be 1:1:2, 2:1:1, 1:2:1, etc.

In some examples, the coils of the heating elements 156 in the respective zones 144, 148, and 152 may not be aligned in the vertical direction. For example, as shown at 182 in FIGS. 1A and 1C, the heating elements 156 of the upper zone 152 and the lower zone 144 are aligned in the vertical direction. In other words, respective coils of the heating elements 156 of the zones 144 and 152 are aligned in the vertical direction. Conversely, the coil of the heating element 156 of the middle zone 148 is offset from (not vertically aligned with) the heating elements 156 of the zones 144 and 152. Accordingly, effects of thermal NUs of any of the heating elements 156 may be diffused.

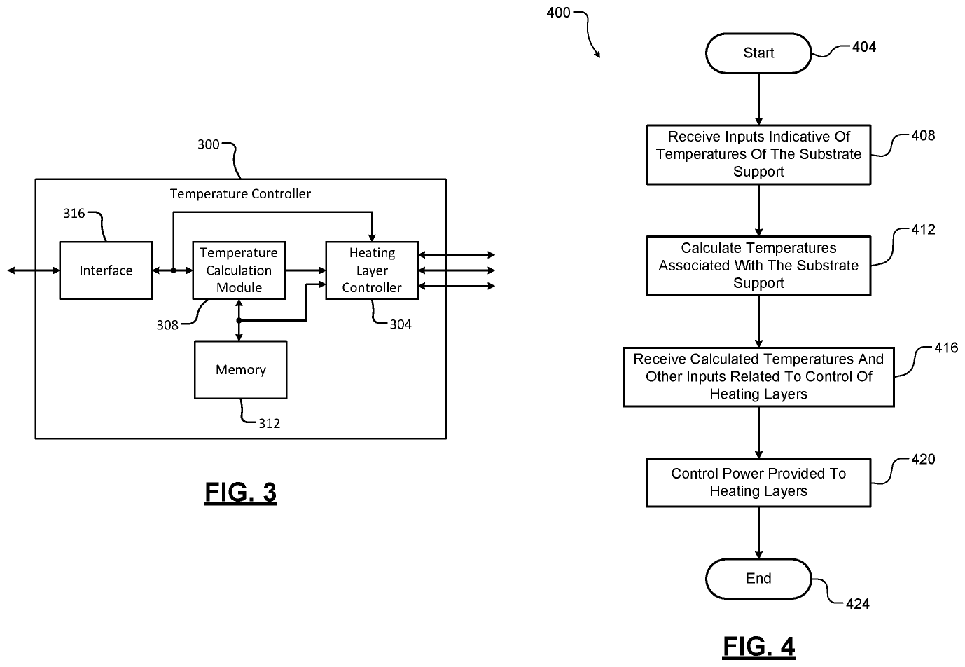

Referring now to FIG. 3, an example temperature controller 300 (e.g., corresponding to the temperature controller 178 of FIG. 1B) according to the principles of the present disclosure includes a heating layer controller 304, a temperature calculation module 308, memory 312, and an interface 316. The interface 316 is configured to receive inputs including, for example, inputs from the controller 176, user inputs, various sensors of the substrate processing system 100, temperature and power feedback, etc. For example only, the memory 312 may include non-volatile memory such as flash memory.

The temperature calculation module 308 calculates temperatures including, for example, respective temperatures of the heating layers/elements, temperatures in different regions of each of the heating layers, temperatures across different regions of the substrate, etc. based on inputs received via the interface 316 and data stored in the memory 312. For example, the memory 312 may store data including, but not limited to, data indicative of the heat map 200, data indicative of a relationship between resistances of heating elements, temperature, and power, data indicative of thermal NUs of the substrate support 104, data indicative of watt density bias in respective radial regions of the substrate support 104, models for calculating temperatures based on various feedback measures, etc. The temperature calculation module 308 provides the calculated temperature values to the heating layer controller 304.

The heating layer controller 304 is configured to receive the calculated temperature values and selectively and independently control the respective heating elements 156 of the heating layers accordingly. For example, the heating layer controller 304 receives the calculated temperature values, process setpoint temperatures (e.g., desired setpoint temperatures respective setpoint temperatures for respective periods and/or process steps, etc.) and/or other parameters from the controller 176 via the interface 316, and data from the memory 312. The process setpoint temperatures may include a single setpoint temperature for each of the heating elements 156 and/or different process setpoint temperatures for each of the respective elements 156. The heating layer controller 304 controls power provided to the heating elements 156 to maintain and/or adjust desired temperatures and to maintain desired zone ratios.

FIG. 4 an example method 400 for controlling the temperature of a substrate support according to the principles of the present disclosure begins at 404. At 408, the method 400 (e.g., the temperature calculation module 308) receives one or more inputs indicative of temperatures associated with the substrate support. At 412, the method 400 (e.g., the temperature calculation module 308) calculates various temperatures associated with the substrate support including, but not limited to, temperatures of respective heating elements, temperature in respective regions or zones of the substrate support, and temperatures across a substrate being processed on the substrate support. The temperature calculation module 308 may be configured to calculate the temperatures based on direct temperature feedback (e.g., signals from sensors arranged to measure temperature, a single temperature sensor in a central region of the substrate support, etc.), measurements and/or inputs corresponding to other parameters associated with temperature (e.g., resistances of the heating elements, power and/or current provided to the heating elements, etc.), one or more models configured to calculate temperature in accordance with various inputs, and/or a combination thereof.

At 416, the method 400 (e.g., the heating layer controller 304) receives inputs including, but not limited to, the calculated temperature values, setpoint temperatures, and relevant data (e.g., from the memory 312) used to determine control of respective heating layers in accordance with the calculated temperature values and the setpoint temperatures. At 420, the method 400 (e.g., the heating layer controller 304) controls power provided to the respective heating layers in accordance with the calculated temperature values, the setpoint temperatures, a desired relationship (e.g., ratio) of power provided to the respective heating layers, a power ratio between inner and power radial zones of the substrate support, and/or respective watt bias densities in different regions of each of the heating layers.

For example, if the substrate support 104 includes N of the vertically-stacked heating elements 156 and a total power P is provided to the heating elements 156, the heating layer controller may provide power to each of the heating elements 156 in accordance with 1/N*P, where P is calculated in accordance with the calculated temperature values and the setpoint temperatures. In other words, P may correspond to a total power required to achieve a setpoint temperature and an equal portion of the power is provided to each of the N heating elements 156. In other examples, different portions of the total power P may be provided to different ones of the heating elements 156. In some examples, the heating layer controller 304 implements a control loop (e.g., a PID loop) configured to control the heating layers to maintain desired temperatures as described above. The method 400 ends at 424.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A substrate support for a substrate processing system configured to perform a deposition process on a substrate, the substrate support comprising:
a pedestal having an upper surface configured to support a substrate; and
N heating layers, wherein the N heating layers are vertically-stacked within the pedestal below the upper surface, and wherein each of the N heating layers includes a respective resistive heating element,
wherein a watt density of the resistive heating element in at least one of the N heating layers varies in at least one radial zone of the substrate support relative to other radial zones of the substrate support.

2. The substrate support of claim 1, wherein each of the resistive heating elements includes a resistive coil.

3. The substrate support of claim 2, wherein at least one of the resistive coils has a different pitch than others of the resistive coils.

4. The substrate support of claim 2, wherein each of the resistive coils has a same pitch.

5. The substrate support of claim 1, wherein the resistive heating elements in at least two of the N heating layers are aligned in a vertical direction.

6. The substrate support of claim 1, wherein the watt density varies in an outer zone of the substrate support.

7. The substrate support of claim 1, wherein the watt density varies in an inner zone of the substrate support.

8. The substrate support of claim 1, wherein each of the resistive heating elements is configured to receive 1/N of an overall power provided to all of the N heating layers in total.

9. The substrate support of claim 1, wherein a diameter of each of the respective resistive heating elements is 90-99% of a diameter of the upper surface of the substrate support.

10. A system comprising the substrate support of claim 1 and further comprising a controller configured to control power provided to the N heating layers based on a desired power ratio between respective ones of the N heating layers.

11. A system, comprising:
a substrate support configured to support a substrate during a deposition process, the substrate support comprising
a pedestal having an upper surface configured to support a substrate, and
N heating layers, wherein the N heating layers are vertically-stacked within the pedestal below the upper surface, and wherein each of the N heating layers includes a respective resistive heating element; and
a controller configured to control power provided to the N heating layers based on a desired power ratio between respective ones of the N heating layers.

12. The system of claim 11, wherein each of the resistive heating elements includes a resistive coil.

13. The system of claim 12, wherein at least one of the resistive coils has a different pitch than others of the resistive coils.

14. The system of claim 12, wherein each of the resistive coils has a same pitch.

15. The system of claim 11, wherein the resistive heating elements in at least two of the N heating layers are aligned in a vertical direction.

16. The system of claim 11, wherein a watt density of the resistive heating element in at least one of the N heating layers varies in at least one radial zone of the substrate support relative to other radial zones of the substrate support.

17. The system of claim 16, wherein the watt density varies in an outer zone of the substrate support.

18. The system of claim 16, wherein the watt density varies in an inner zone of the substrate support.

19. The system of claim 11, wherein each of the resistive heating elements is configured to receive 1/N of an overall power provided to all of the N heating layers in total.

20. The system of claim 11, wherein a diameter of each of the respective resistive heating elements is 90-99% of a diameter of the upper surface of the substrate support.
